(19) United States
(12) Patent Application Publication
(10) Pub. No.: US 2015/0241244 A1
(43) Pub. Date: Aug. 27, 2015

(54) LOW-POWER ORIENTATION ESTIMATION

(71) Applicant: George Hsu, Boca Raton, FL (US)

(72) Inventor: George Hsu, Boca Raton, FL (US)

(73) Assignee: PNI SENSOR CORPORATION, Santa Rosa, CA (US)

(21) Appl. No.: 14/619,396

(22) Filed: Feb. 11, 2015

Related U.S. Application Data
(60) Provisional application No. 61/943,412, filed on Feb. 23, 2014.

(51) Int. Cl. G01C 25/00; G01P 15/00; G01R 33/02; G01C 19/00

(52) U.S. Cl. CPC G01C 25/00; G01C 19/00; G01P 15/00; G01R 33/02

(57) ABSTRACT

Apparatuses, methods and systems apparatus for low-power orientation estimation are disclosed. One apparatus includes an accelerometer, wherein the accelerometer generates a sensed acceleration of the accelerometer, a magnetic sensor, wherein the magnetic sensor generates a sensed magnetic field ambient to the magnetic sensor, a gyroscope, wherein the gyroscope generates a sensed orientation of the gyroscope, wherein at least one of the accelerometer, the magnetic sensor and the gyroscope operates at a first sampling rate. The apparatus further includes an adaptive filter. The adaptive filter operates at a second rate to generate an orientation estimate (Q) based on computational processing of at least the sensed acceleration, the sensed magnetic field, and the sensed orientation of the gyroscope, wherein the second rate is different than the first sampling rate.

### RELATED APPLICATIONS

This patent application claims priority to U.S. Provisional Patent Application Ser. No. 61/943,412, filed Feb. 23, 2014, which is herein incorporated by reference.

### FIELD OF THE EMBODIMENTS

The described embodiments relate generally to estimating an orientation. More particularly, the described embodiments relate to apparatuses, methods and systems for low-power orientation and/or motion estimation.

### BACKGROUND

Adaptive filters used to determine attitude and orientation are computationally intensive, especially when containing a high number of state variables. When such adaptive filters are used to fuse the outputs obtained from a combination of gyroscopes, magnetometers and accelerometers, the gyroscope provides the instantaneous angular displacement, while the magnetometer and accelerometer are used to correct the longer-term errors that accumulate in the gyroscope's output. These errors include bias offset drift, saturation and non-continuous displacements caused by shock. The two main computational threads in such systems are the gyroscope propagation that produces the orientation estimate and the adaptive filter loop that produces the magnetometer and accelerometer-based error correction estimate that the most current gyro propagation result must be corrected by.

Traditional implementations of adaptive filters have all been implemented in a synchronous manner wherein each computational cycle consists of a new data sample from each of the sensors to compute a new gyroscope propagation value and adaptive filter result. This data sampling and the accompanying computations must be performed at a high enough rate to ensure the timely and accurate measurement of the motions of interest. The sampling and computational loop rates are often as high as several hundred samples per second in order to properly capture human scale motion during normal activity. However, power consumption scales linearly with each computation that is required to produce an orientation result. As all modern mobile devices are powered by self-contained battery sources, power consumption is an important parameter to optimize. An obvious approach to minimizing power consumption is to simply reduce the frequency rates of the sampling and computation. However, arbitrarily reducing these rates is not desirable as the accuracy of the motion measurement can be materially compromised.

Based upon the characteristics of the specific sensors and how each is employed within an adaptively filtered system, the gyroscope is the only sensor that needs to be sampled at a relatively high rate in order to generate a timely and responsive gyroscope propagation value. The magnetometer and accelerometer sensors can be sampled at a much slower rate to be used in each new adaptive filter loop update, which itself can also be set to yet a slower rate than the magnetometer and accelerometer sample rates. The timing of these disparate sampling and computational rates require careful management of all the constituent pieces, but the result is a significant reduction in the number of samples and computational cycles and a commensurate significant reduction in power consumption without any degradation in motion measurement performance.

It is desirable to have apparatuses, methods, and systems for low-power attitude and orientation estimation with no loss in performance.

### SUMMARY

An embodiment includes an apparatus. The apparatus includes an accelerometer, wherein the accelerometer generates a sensed acceleration of the accelerometer, a magnetic sensor, wherein the magnetic sensor generates a sensed magnetic field ambient to the magnetic sensor, a gyroscope, wherein the gyroscope generates a sensed orientation of the gyroscope, wherein at least one of the accelerometer, the magnetic sensor and the gyroscope operates at a first sampling rate. The apparatus further includes an adaptive filter. The adaptive filter operates at a second rate to generate an orientation estimate (Q) based on computational processing of at least the sensed acceleration, the sensed magnetic field, and the sensed orientation of the gyroscope, wherein the second rate is different than the first sampling rate.

Another embodiment includes a method for low-power sensing an orientation. The method includes sensing, by an accelerometer, an acceleration of the accelerometer, sensing, by a magnetic sensor, a magnetic field ambient to the magnetic sensor, sensing, by a gyroscope, an orientation of the gyroscope, wherein at least one of the accelerometer, the magnetic sensor and the gyroscope operates at a first sampling rate. The method further includes generating, by an adaptive filter, an orientation estimate (Q) at a second rate based on computational processing of at least the sensed acceleration, the sensed magnetic field, and the sensed orientation of the gyroscope, wherein the second rate is different than the first sampling rate.

Other aspects and advantages of the described embodiments will become apparent from the following detailed description, taken in conjunction with the accompanying drawings, illustrating by way of example the principles of the described embodiments.

### BRIEF DESCRIPTION OF THE DRAWINGS

FIG. 1 shows a low-power orientation and/or motion estimation apparatus, according to an embodiment.

FIG. 2 shows a low-power orientation and/or motion estimation apparatus, according to another embodiment.

FIG. 3 shows a low-power orientation and/or motion estimation apparatus, according to another embodiment.

FIG. 4 shows a low-power orientation and/or motion estimation apparatus that includes an additional input, according to another embodiment.

FIG. 5 shows is a flow chart that includes steps of a method for low-power sensing of an orientation, according to an embodiment.

FIG. 6 shows a low-power orientation and/or motion estimation apparatus that includes a plurality of adaptive filters, according to an embodiment.

FIG. 7 shows a low-power orientation and/or motion estimation apparatus that includes a plurality of adaptive filters and selectable human models, according to an embodiment.

### DETAILED DESCRIPTION

The described embodiments provide for apparatuses, methods, and systems for low-power sensing of an orientation and/or motion. The sensed orientation and/or motion can be of, for example, a computing device or mobile device of a user. An orientation and/or motion of a user of the computing device can be inferred by the orientation and/or motion of computing device. For an embodiment, the low-power orientation sensing apparatus includes at least an accelerometer, a gyroscope, and an adaptive filter, wherein a sampling rate of at least one of the accelerometer and the gyroscope includes a sampling frequency that is different than a clock frequency of the adaptive filter. For an embodiment, the clock frequency of the adaptive filter is less than the sampling rate of the accelerometer and the gyroscope. For an embodiment, the adaptive filters further receive an input from a magnetic sensor. Further, at least some embodiments include additional inputs, such as, a received radio frequency (RF) received by the computing device.

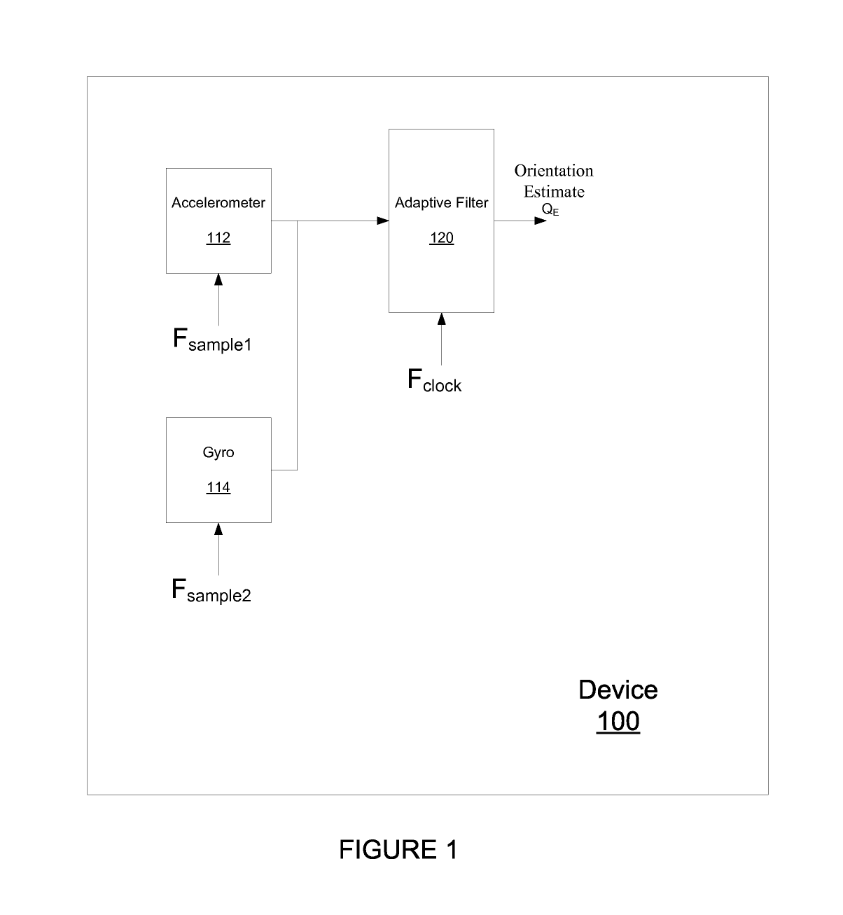

FIG. 1 shows a low-power orientation and/or motion estimation apparatus, according to an embodiment. As shown, the apparatus (device 100) includes an accelerometer 112 and a gyroscope 114. The accelerometer 112 senses acceleration of the device 100, and the gyroscope 114 senses an orientation of the gyroscope 114, which provides a representation of the orientation of the device 100. As shown, the accelerometer 112 is sampled by a clock (Fₛₐₘₚₗₑ₁) and the gyroscope is sampled by a clock (Fₛₐₘₚₗₑ₂). For an embodiment, the sampling frequency (Fₛₐₘₚₗₑ₁) of the accelerometer 112 and the sampling frequency (Fₛₐₘₚₗₑ₂) of the gyroscope are the same, but for at least some other embodiments, they are different.

The sensed signals of the accelerometer 112 and the gyroscope 114 are received by an adaptive filter 120. Based on the received sensed signals, the adaptive filter 120 generates an orientation estimate (Q) of the device 100. For an embodiment, the orientation estimate (Q) includes a Quaternion. Quaternions, also known as versors, provide a convenient mathematical notation for representing orientations and rotations of objects in three dimensions.

For an embodiment, the processing of the adaptive filter 120 is clocked at a frequency F_{clock}. For an embodiment, the frequency F_{clock} of the processing of the adaptive filter 120 is different than at least one of the sampling frequency (Fₛₐₘₚₗₑ₁) of the accelerometer 112 and the sampling frequency (Fₛₐₘₚₗₑ₂) of the gyroscope.

The processing of the adaptive filter 120 consumes power. The faster the processing (the higher the clock frequency), the greater the amount of power consumed by the adaptive filter 120. Practically, it would be more convenient to merely use the same clock for the sampling of the sensors 112, 114 and the processing of the adaptive filter 120. However, by sampling at a first rate, and clocking the processing of the adaptive filter at a second rate, the frequency of the first rate and the second rate can be adjusted or selected only as high as needed to obtain a desired level of performance.

For instance, a criterion for setting the clock rate of the adaptive filter 120 can be based upon the characteristics of the dynamic motions to be measured and the level of accuracy and responsiveness required by the application. For example, the clock of the adaptive filter 120 can be set to a higher rate when the device orientation is used as an input for a motion-based video gaming controller. Specifically, in game play, rapid and fairly vigorous motion and changes in direction of the device are common, which causes discontinuities in the gyroscope propagation measurements due to shock. These errors due to discontinuities can become noticeable during game play if they are not quickly corrected for. On the other hand, a navigation oriented application, such as autonomous vehicle guidance control or pedestrian dead reckoning can operate with acceptable accuracy at lower clock rates of the adaptive filter 120 as their dynamic motions tend to be smoother and do not cause shock induced gyroscope propagation errors, and thus a power savings can be achieved without sacrificing accuracy.

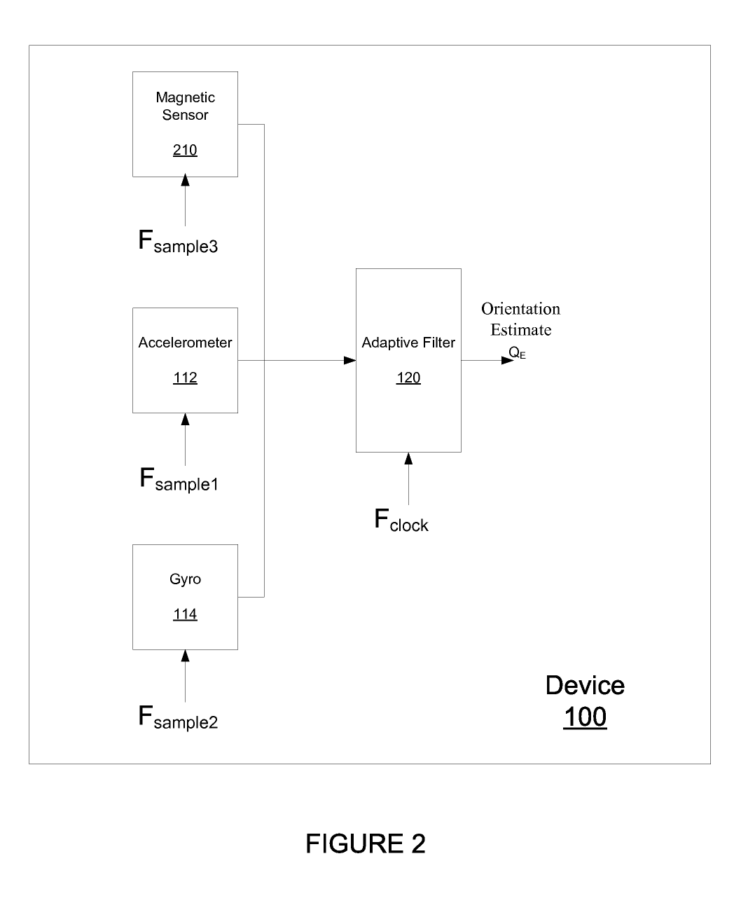

FIG. 2 shows a low-power orientation and/or motion estimation apparatus, according to another embodiment. This embodiment further includes a magnetic sensor 210, wherein the magnetic sensor 210 generates a sensed magnetic field ambient to the magnetic sensor 210. Further, the adaptive filter 120 is operative to receive the sensed magnetic field and generate the estimated orientation (Q).

Traditionally, the magnetic sensor 210 provides the direct measurements of the Earth's magnetic field to construct a second vector in three-dimensional space that combines with the gravitational vector to form the basis of that three dimensional space. This basis can be used to define the rotational coordinates of a device's rotational position within its basis space. However, the use of the magnetic field vector in many adaptive filter implementations is to provide the Earth-frame yaw, azimuth or heading reference for correcting its gyroscope propagated counterpart after an adaptive filter is applied. The accelerometer is used for the same purpose, but for the pitch and roll components of rotation instead.

As shown, the magnetic sensor 210 includes a sampling frequency (Fₛₐₘₚₗₑ₃). For an embodiment, the sampling frequency (Fₛₐₘₚₗₑ₁) of the accelerometer 112, the sampling frequency (Fₛₐₘₚₗₑ₂) of the gyroscope, and the sampling frequency (Fₛₐₘₚₗₑ₃) of the magnetic sensor are the same, but for at least some other embodiments, they are different. For an embodiment, the frequency F_{clock} of the processing of the adaptive filter 120 is different than at least one of the sampling frequency (Fₛₐₘₚₗₑ₁) of the accelerometer 112, the sampling frequency (Fₛₐₘₚₗₑ₂) of the gyroscope, and the sampling frequency (Fₛₐₘₚₗₑ₃) of the magnetic sensor. For an embodiment, the frequency F_{clock} of the processing of the adaptive filter 120 is less than at least one of the sampling frequency (Fₛₐₘₚₗₑ₁) of the accelerometer 112, the sampling frequency (Fₛₐₘₚₗₑ₂) of the gyroscope, and the sampling frequency (Fₛₐₘₚₗₑ₃) of the magnetic sensor.

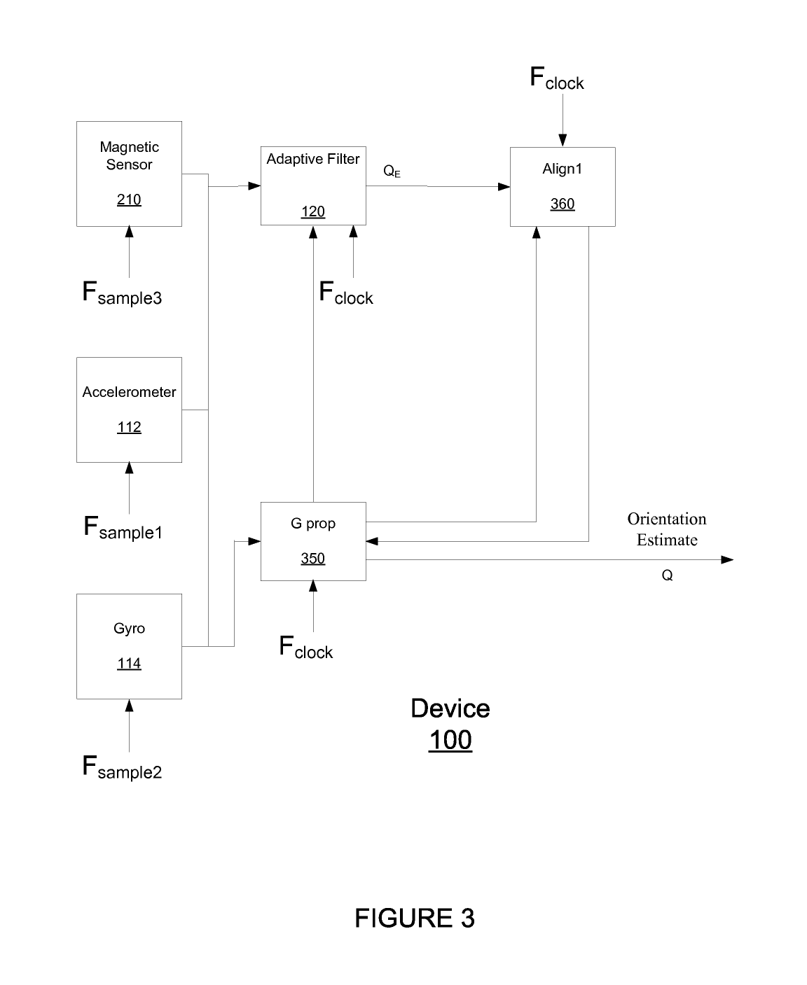

FIG. 3 shows a low-power orientation and/or motion estimation apparatus, according to another embodiment. This embodiment further includes a gyroscope propagation device 350 and an alignment block Align 360. The alignment block 360 receives the output from the adaptive filter 120, and generates an alignment output for the gyroscope propagation device 350. The gyroscope propagation device 350 generates an output for the adaptive filter 120.

The gyroscope propagation device (propagation device 350) maintains the attitude and orientation as calculated solely based upon the gyroscope 114 outputs. For direct angular output gyroscopes this propagated value is determined by a reading of an angular encoder or the addition and subtraction of angular displacements calculated from an initial zero position. For angular rate sensor based gyroscopes, such as MEMS gyroscopes, the propagated angular displacement is calculated by an integration of the angular rate sensor output. In addition to the intrinsically higher noise characteristics possessed by MEMS gyroscopes, the integration step adds additional errors caused by the unknown constant of integration, as well as the Brownian random walk of the gyroscope offset due to the integration of spectral noise. The adaptive filter update loop (in FIG. 3, the adaptive filter update loop includes, for example, adaptive filter 120, alignment block 360, and propagation device 350) takes as inputs the measured magnetic sensor (of the magnetic sensor 210), sensed acceleration (of the accelerometer 112), the gyroscope propagation value and the system's output quaternion value and calculates an error quaternion (such as, QE output of the adaptive filter 120) based upon the specific weighting of the state variable dependent coefficients within the adaptive filter 120. The error quaternion represents the filter's best estimate of the variance between the current gyroscope propagated value and the true angular rotations with respect to a known reference frame, such as the Earth's or device's reference frames. Once the error quaternions are calculated, the alignment block 360 simply multiplies the current gyro propagated value output by 350 by the error quaternion QE to produce the system's new output quaternions Q. These output quaternions, Q is the value that best represent the true rotational position of the device in three dimensional space, and as previously stated, are also fed back into the adaptive filter update loops as one of the inputs for the calculation of the next error quaternions QE1. For at least some embodiments, the structure of adaptive filters 120 is recursive and current outputs are based upon results calculated from the outputs of prior measurement steps.

For an embodiment, the adaptive filter 120 is implemented using Kalman filters.

Kalman Filters

For an embodiment, the Kalman filters, includes a series of measurements observed over time, containing noise (random variations) and other inaccuracies, and produces estimates of unknown variables that tend to be more precise than those based on a single measurement alone. More formally, a Kalman filter operates recursively on streams of noisy input data to produce a statistically optimal estimate of the underlying system state. The Kalman filter has numerous applications in technology. A common application is for guidance, navigation and control of vehicles, particularly aircraft and spacecraft.

For an embodiment, the Kalman filter produces estimates of the current state variables, along with their uncertainties. Once the outcome of the next measurement (necessarily corrupted with some amount of error, including random noise) is observed, these estimates are updated using a weighted average, with more weight being given to estimates with higher certainty. Because of the Kalman filter's recursive nature, it can run in real time using only the present input measurements and the previously calculated state and its uncertainty matrix, while no additional past information is required.

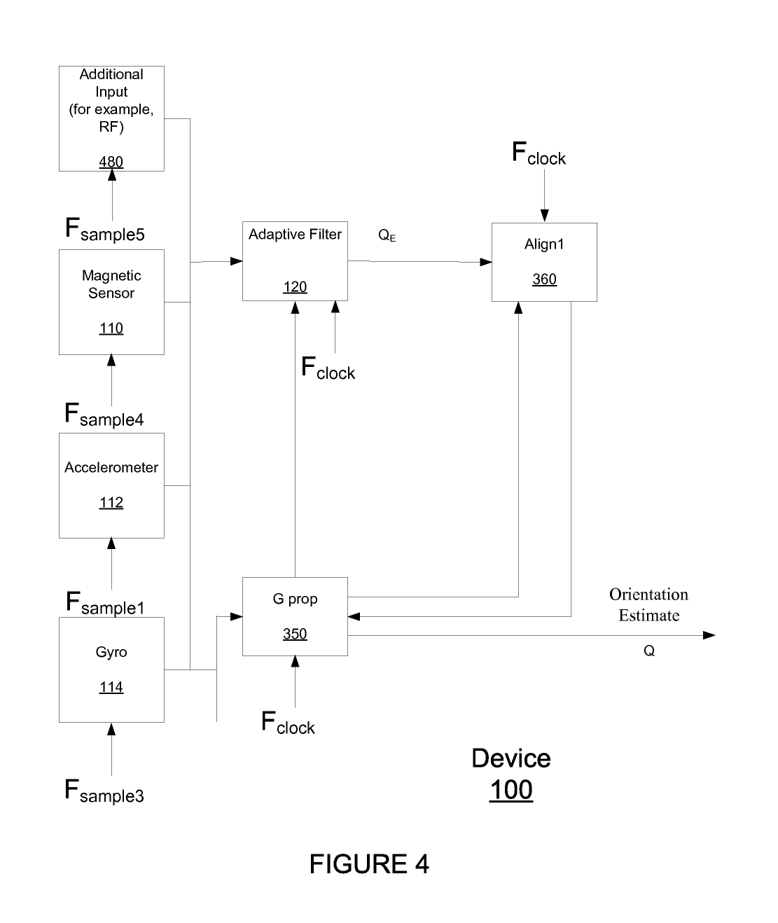

FIG. 4 shows a low-power orientation and/or motion estimation apparatus that includes an additional input 480, according to another embodiment. For an embodiment, the additional input 480 includes a radio frequency (RF) signal. Accordingly, for an embodiment, at least one of the adaptive filter 120 further operative to receive the RF signal received by the apparatus.

Exemplary RF signals include, but are not limited to, cellular wireless signals, WiFi wireless signals, and/or Bluetooth signals. Each of this exemplary RF signals can be used to additionally characterize orientation/motion of the user and computing device of the user. For an embodiment, the adaptive filters are additionally or alternatively tuned based on characteristics of the RF signal being received.

The elements of RF signals that can be adaptively weighted are the Received Signal Strength Indicator (RSSI), Time of Flight (ToF) of the incoming signal, and the direction of the incoming signal if the orientation of the device relative to Earth frame is known.

It is to be understood that while an additional RF input is shown and described, it is to be understood that other additional inputs can be included as well. For example, for a pressure sensor can be utilized for elevation determination of the computing device. For example, proximity sensors can be utilized for determining distances to extremely nearby objects.

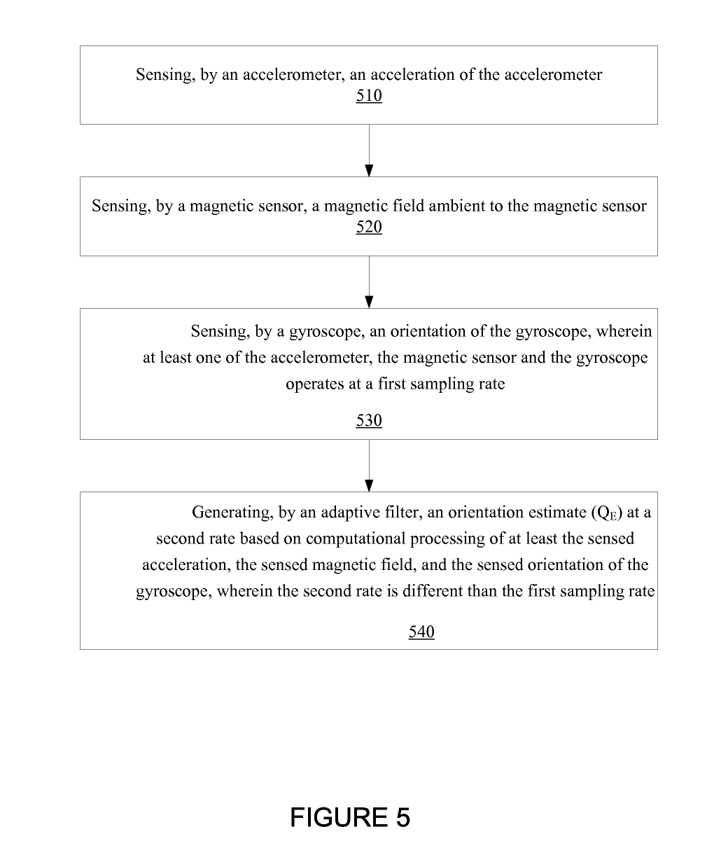

FIG. 5 shows is a flow chart that includes steps of a method for low-power sensing of an orientation, according to an embodiment. A first step 510 includes sensing, by an accelerometer, an acceleration of the accelerometer. A second step 520 includes sensing, by a magnetic sensor, a magnetic field ambient to the magnetic sensor. An embodiment includes the accelerometer and the gyroscope, but does not necessarily include the magnetic sensor. A third step 530 includes sensing, by a gyroscope, an orientation of the gyroscope, wherein at least one of the accelerometer, the magnetic sensor and the gyroscope operates at a first sampling rate. An embodiment includes the accelerometer and the gyroscope, but does not necessarily include the magnetic sensor. A fourth step 540 includes generating, by an adaptive filter, an orientation estimate (Q) at a second rate based on computational processing of at least the sensed acceleration, the sensed magnetic field, and the sensed orientation of the gyroscope, wherein the second rate is different than the first sampling rate.

As stated, for at least some embodiments, the accelerometer, the magnetic sensor and the gyroscope operates at a first sampling rate. For at least some embodiments, operating at the first sampling rate includes a sense signal being sampled at the first sampling rate. That is, at least one of a sensed acceleration signal of the accelerometer is sampled at the first sampling rate, a sensed magnetic signal of the magnetic sensor is sampled at the first sampling rate, or a sense gyroscope signal of the gyroscope is sampled at the first sampling rate.

An embodiment further includes sensing, by a magnetic sensor, magnetic field ambient to the magnetic sensor, and wherein the orientation estimate (Q) generated at the second rate is based on computational processing of at least the sensed acceleration, the sensed magnetic field, and the sensed orientation of the gyroscope.

For an embodiment, the second rate is not periodic. For an embodiment, the adaptive filter operates asynchronously. That is, the clock rate of the adaptive filter does not have to be related to the sampling frequencies of the sensors.

For an embodiment, the adaptive filter operates based upon sensed motion. That is, if no motion is sensed by the computing device, for an embodiment, the clock of the adaptive filter is reduced to save power. For a specific embodiment, the adaptive filter remains inoperable during a period of time in which no motion of the apparatus is sensed. Conversely, for at least some embodiments, the adaptive filter remains operable only during periods of time in which motion of greater than a threshold is sensed.

For an embodiment, the second rate is adaptively selected. For an embodiment, the second rate is adaptively selected based upon a sensed level of motion of the apparatus. That is, if the motion of the apparatus is low, the sensed motion can be determined at a lower rate, and therefore, the second rate of computational processing of the adaptive filter of at least the sensed acceleration, and the sensed orientation of the gyroscope can be lower. Conversely, if the motion of the apparatus is higher, the second rate of the computational processing needs to be higher. However, the second rate is ideally selected to be as low as required in order to obtain a preferred level of performance, thereby only using as much computational processing power as needed.

For at least some embodiments, the first sampling rate is adaptively selected. For at least some embodiments, the first sampling rate is adaptively selected based on sensed motion of the apparatus. For at least some embodiments, the first sampling rate is adaptively selected based on a level of sensed motion of the apparatus. For at least some embodiments, the first sampling rate is adaptively selected based on internal parameters of the apparatus.

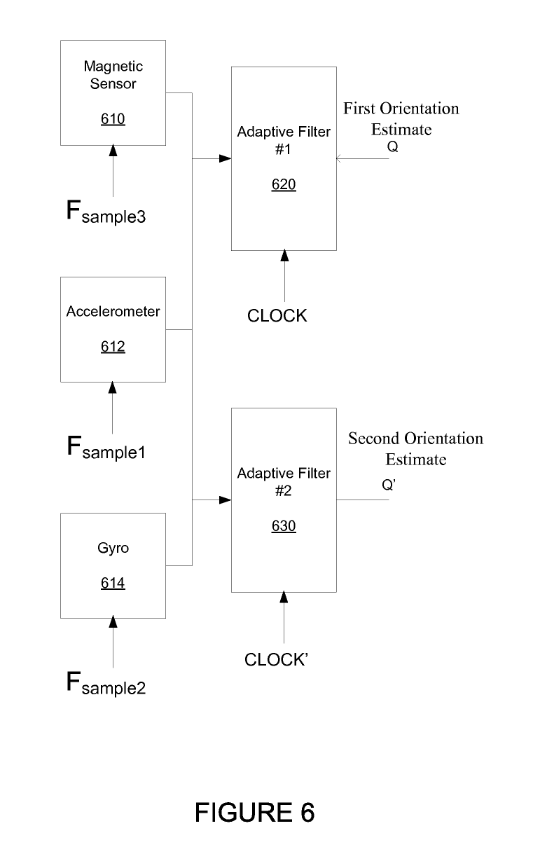

FIG. 6 shows a low-power orientation and/or motion estimation apparatus that includes a plurality of adaptive filters, according to an embodiment. A first adaptive filter 620 generates a first orientation estimate based on the magnetic field of the magnetic sensor 610, sensed acceleration of the accelerometer 612 and the sensed orientation of the gyroscope 614. Further, a second adaptive filter 630 generates a second orientation estimate based on the magnetic field of the magnetic sensor 610, sensed acceleration of the accelerometer 612 and the sensed orientation of the gyroscope 614.

As shown, the first adaptive filter 620 and the second adaptive filter 630 include clocks (CLOCK and CLOCK′) that clock the processing of the adaptive filters 620, 630. For an embodiment, the rate of the clock of the first adaptive filter 620 is the same as the rate of the clock of the second adaptive filter 630. For an embodiment, the rate of the clock of the first adaptive filter 620 is different as the rate of the clock of the second adaptive filter 630. The clock rates can be selected for each adaptive filter based on the type of motion being sensed by each adaptive filter, which can be different for each adaptive filter.

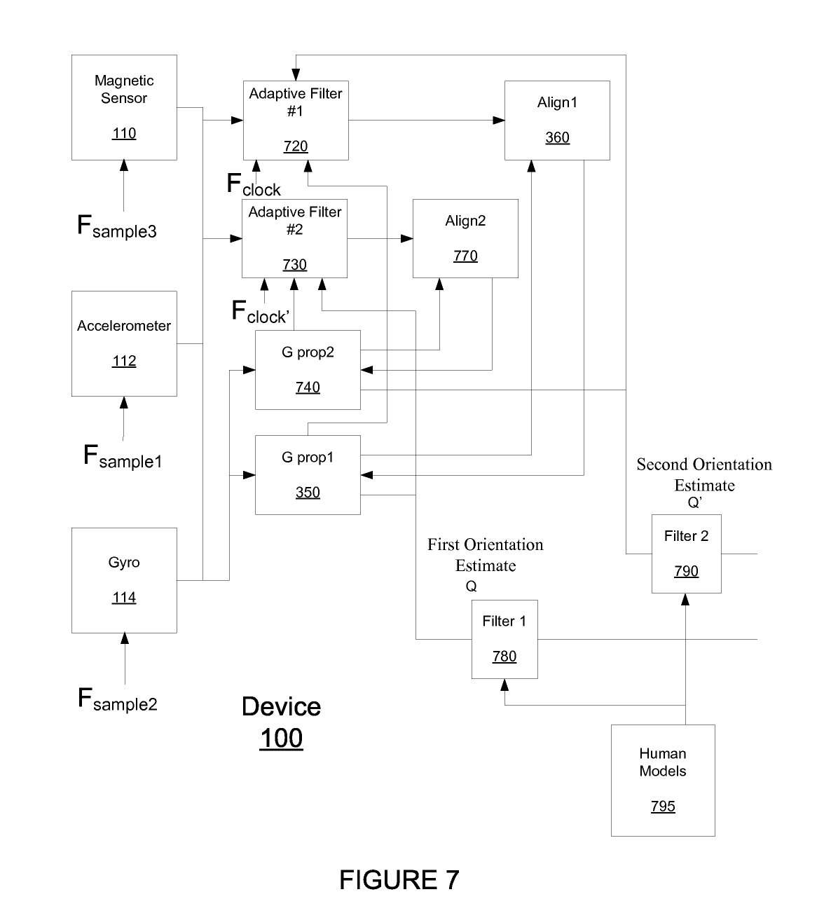

FIG. 7 shows a low-power orientation and/or motion estimation apparatus that includes a plurality of adaptive filters and selectable human models, according to an embodiment. This embodiment further includes gyroscope propagation device 740 and an alignment block Align2 770. The alignment block 770 receives the output from the adaptive filter 730, and generates an alignment output for the gyroscope propagation device 770. The gyroscope propagation device 740 generates an output for the adaptive filter 730.

For an embodiment, the human models are incorporated into the adaptive filters, for example, through external filtering (filters 780, 790) at the outputs of the adaptive filters 720, 730. While depicted in FIG. 7 as being external to the adaptive filters, clearly, the functionality of the filters 780, 790 can be incorporated into the adaptive filters 720, 730. The point is that human models can be accessed from, for example, a database 795, and the human models effectively tune the corresponding adaptive filter to pass (not filter) motion characteristics that are related to a particular human motion.

For at least some embodiments, the human motion models include device acceleration profiles when the computing device is located at particular points on the human body. The main ones include, for example, the computing device in pocket, device in hand in front, device in hand at side and device next to head on the ear. While walking there are very different acceleration characteristics at each of these locations. The idea is to quantify these acceleration characteristics to identify in which position on the body amongst these main categories the device is, and then to modulate the accelerations measured at that location to remove the components of acceleration due to the devices specific location, so that the remaining acceleration is linear acceleration of the person's center of gravity, which, when compared to the magnitudes of these location based accelerations, tend to be many times smaller in signal strength.

Although specific embodiments have been described and illustrated, the described embodiments are not to be limited to the specific forms or arrangements of parts so described and illustrated. The embodiments are limited only by the appended claims.

What is claimed:

1. An apparatus, comprising:
an accelerometer, wherein the accelerometer generates a sensed acceleration of the accelerometer;
a gyroscope, wherein the gyroscope generates a sensed orientation of the gyroscope; wherein
at least one of the accelerometer, and the gyroscope operates at a first sampling rate; and
an adaptive filter, the adaptive filter operating at a second rate to generate an orientation estimate (Q) based on computational processing of at least the sensed acceleration, and the sensed orientation of the gyroscope, wherein the second rate is different than the first sampling rate.

2. The apparatus of claim 1, further comprising a magnetic sensor, wherein the magnetic sensor generates a sensed magnetic field ambient to the magnetic sensor.

3. The apparatus of claim 1, wherein the second rate is not periodic.

4. The apparatus of claim 1, wherein, the adaptive filter operates asynchronously.

5. The apparatus of claim 1, wherein the adaptive filter operates based upon sensed motion.

6. The apparatus of claim 1, wherein the adaptive filter remain inoperable during period of time in which no motion of the apparatus is sensed.

7. The apparatus of claim 1, wherein the second rate is adaptively selected.

8. The apparatus of claim 1, wherein the second rate is adaptively selected based upon a sensed level of motion of the apparatus.

9. The apparatus of claim 1, wherein the first sampling rate is adaptively selected.

10. The apparatus of claim 9, wherein the first sampling rate is adaptively selected based on sensed motion of the apparatus.

11. The apparatus of claim 9, wherein the first sampling rate is adaptively selected based on a level of sensed motion of the apparatus.

12. The apparatus of claim 9, wherein the first sampling rate is adaptively selected based on internal parameters of the apparatus.

13. A method of estimating an orientation, comprising:
sensing, by an accelerometer, an acceleration of the accelerometer;
sensing, by a gyroscope, an orientation of the gyroscope; wherein
at least one of the accelerometer and the gyroscope operates at a first sampling rate; and
generating, by an adaptive filter, an orientation estimate (QE) at a second rate based on computational processing of at least the sensed acceleration and the sensed orientation of the gyroscope, wherein the second rate is different than the first sampling rate.

14. The method of claim 13, further comprising sensing, by a magnetic sensor, magnetic field ambient to the magnetic sensor.

15. The method of claim 13, wherein the second rate is not periodic.

16. The method of claim 13, wherein, the adaptive filter operates asynchronously.

17. The method of claim 13, wherein the adaptive filter operates based upon sensed motion.

18. The method of claim 13, wherein the adaptive filter remain inoperable during period of time in which no motion of the apparatus is sensed.

19. The method of claim 13, wherein the second rate is adaptively selected.

20. The method of claim 13, wherein the second rate is adaptively selected based upon a sensed level of motion of the apparatus.
